(19) United States
(12) Patent Application Publication
(10) Pub. No.: US 2026/0282631 A1
(43) Pub. Date: Sep. 17, 2026

(54) DISPLAY DEVICE

(71) Applicant: AUO Corporation, Hsinchu City (TW)

(72) Inventors: Yueh-Chi WU, Hsinchu City (TW); Wang-Shuo KAO, Hsinchu City (TW); Shu-Wen LIAO, Hsinchu City (TW); Ti-Kuei YU, Hsinchu City (TW); Ya-Ling HSU, Hsinchu City (TW)

(21) Appl. No.: 19/386,481

(22) Filed: Nov. 12, 2025

(30) Foreign Application Priority Data
Mar. 11, 2025 (TW) 114108987

(51) Int. Cl. H10H 29/30; H10H 29/34; G02F 1/1362; H10K 59/35

(52) U.S. Cl. CPC H10H 29/352; H10H 29/345; G02F 1/1362; H10K 59/352; H10K 59/353

(57) ABSTRACT

A display device includes an array substrate having a first display area and a second display area adjacent to the first display area. The array substrate includes first pixel rows and second pixel rows disposed in the first display area and the second display area in a first direction, respectively. Each first pixel row and each second pixel row include first pixels and second pixels disposed in a second direction, respectively. The width of each second pixel in the second direction is the same as the width of each first pixel in the second direction, and the display medium of each second pixel is different from the display medium of each first pixel. The display medium of each second pixel includes first, second and third micro-LEDs, and in each second pixel, two of the first, second and third micro-LEDs overlap in the first direction.

### CROSS - REFERENCE TO RELATED APPLICATION

This application claims priority to Taiwan Application Serial Number 114108987, filed Mar. 11, 2025, which is herein incorporated by reference in its entirety.

### BACKGROUND

### Field of Invention

The present disclosure relates to a display device. More particularly, the present disclosure relates to a display device having display areas that use different display mediums.

### Description of Related Art

With the widespread adoption of full-screen displays and the pursuit of unibody designs in consumer electronics, under-display sensing technology has become a key development focus for small-to-medium-sized display devices. Conventional display medium, such as liquid crystal units or organic light-emitting diodes (OLEDs), typically require backlighting or have complex pixel circuitry, it is difficult to achieve a transparent display area that overlaps with optical sensors (such as lenses).

However, if the entire display device employs a display medium capable of achieving a transparent display area that overlaps with the optical sensor, such as micro light-emitting diodes (micro-LEDs, μLEDs), the production cost becomes prohibitively high. Therefore, developing a display device that has display areas with different display mediums while maintaining good display quality is one of the goals of this technical field.

### SUMMARY

At least one embodiment of the present disclosure provides a display device having display areas that use different display mediums, and which can improve display quality.

The display device according to at least one embodiment of the present disclosure includes an array substrate having a first display area and a second display area adjacent to the first display area. The array substrate includes multiple first pixel rows disposed in the first display area in a first direction and multiple second pixel rows disposed in the second display area in the first direction. Each of the first pixel rows includes multiple first pixels disposed in a second direction perpendicular to the first direction. Each of the second pixel rows includes multiple second pixels disposed in the second direction. The width of each of the second pixels in the second direction is the same as the width of each of the first pixels in the second direction, and the display medium of each of the second pixels is different from the display medium of each of the first pixels. The display medium of each of the second pixels includes a first micro-LED, a second micro-LED and a third micro-LED. In each of the second pixels, two of the first micro-LED, the second micro-LED and the third micro-LED overlap in the first direction.

The display device according to at least another embodiment of the present disclosure includes an array substrate having a first display area and a second display area adjacent to the first display area. The array substrate includes multiple first pixel rows disposed in the first display area in a first direction and multiple second pixel rows disposed in the second display area in the first direction. Each of the first pixel rows includes multiple first pixels disposed in a second direction perpendicular to the first direction. Each of the second pixel rows includes multiple second pixels disposed in the second direction. The width of each of the second pixels in the second direction is the same as the width of each of the first pixels in the second direction, and the display medium of each of the second pixels is different from the display medium of each of the first pixels. The display medium of each of the second pixels includes a first micro-LED, a second micro-LED and a third micro-LED. Each of the second pixels is equally divided into a first horizontal region, a second horizontal region, and a third horizontal region in sequence in the first direction, one of the first micro-LED, the second micro-LED and the third micro-LED is disposed in the first horizontal region, and more than half of a orthographic projection of the one of the first micro-LED, the second micro-LED and the third micro-LED on the array substrate is located in the first horizontal region.

### BRIEF DESCRIPTION OF THE DRAWINGS

FIG. 1 is a schematic top view of a display device according to at least one embodiment of the present disclosure.

FIG. 2 is an enlarged diagram of region A of an array substrate in FIG. 1.

FIG. 3 is an enlarged diagram of a region of an array substrate of a display device according to at least another embodiment of the present disclosure.

FIGS. 4A-4F are enlarged diagrams of regions of array substrates of display devices according to at least another embodiments of the present disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words "about", "approximately" or "substantially" used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are "substantially parallel" or "substantially perpendicular," where "substantially parallel" and "substantially perpendicular," respectively, mean that parallelism and perpendicularity between the two objects can include non-parallelism and non-perpendicularity caused by permissible deviation ranges.

In addition, "about" may mean within one or more standard deviations of the above values, such as within ±30%, ±20%, ±10%, or ±5%. Such words as "about", "approximately", or "substantially" as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as "below," "under," "above," "on," and the like, are intended to facilitate the recitation of a relative relationship between one element or feature and another as depicted in the drawings. The true meaning of these spatial relative terms includes other orientations. For example, the relationship between one element and another may change from "below" and "under" to "above" and "on" when the drawing is turned 180 degrees up or down. In addition, spatially relative descriptions used in the present disclosure should be interpreted in the same manner.

It should be understood that while the present disclosure may use terms such as "first", "second", "third" to describe various elements or features, these elements or features should not be limited by these terms. These terms are primarily used to distinguish one element from another, or one feature from another. In addition, the term "or" as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

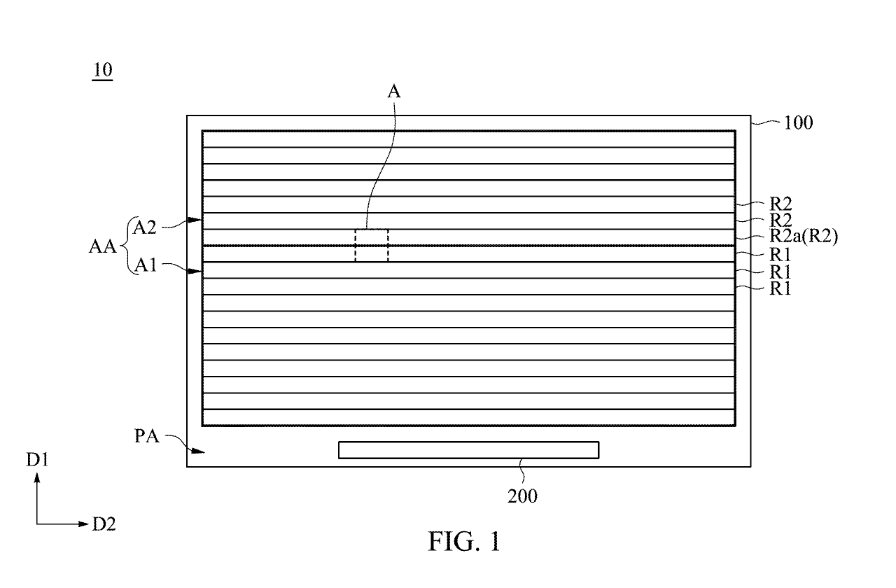

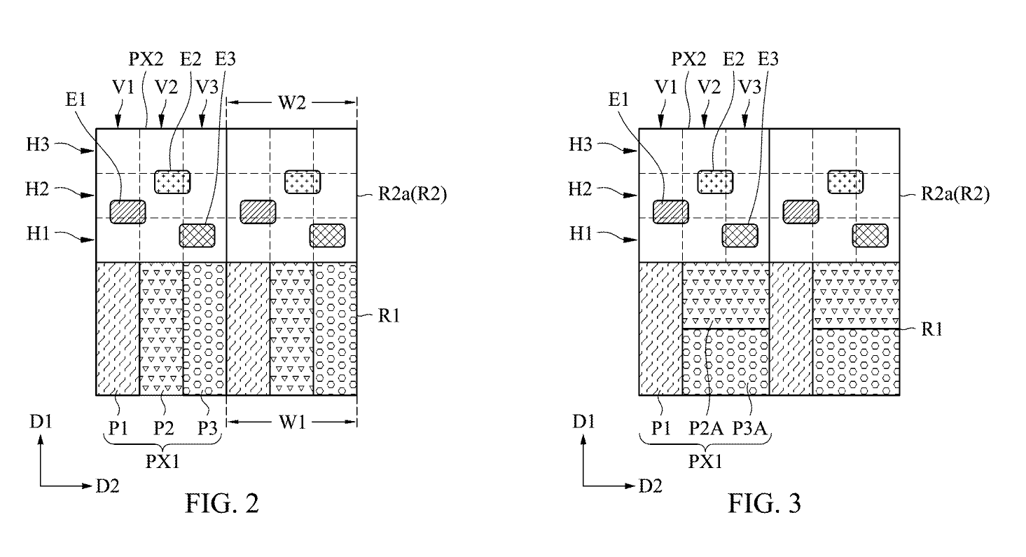

FIG. 1 is a schematic top view of a display device 10 according to at least one embodiment of the present disclosure. FIG. 2 is an enlarged diagram of region A of an array substrate 100 in FIG. 1. Referring to FIGS. 1 and 2, the display device 10 has a display area AA and a peripheral area PA adjacent to the display area AA. The display area AA has a first display area A1 and a second display area A2 adjacent to the first display area A1. The display device 10 includes an array substrate 100.

The array substrate 100 has the first display area A1 and the second display area A2 adjacent to the first display area A1, and includes multiple first pixel rows R1 and multiple second pixel rows R2. The first pixel rows R1 are disposed in the first display area A1 in the first direction D1, and the first pixel row R1 includes multiple first pixels PX1 disposed in a second direction D2 that is substantially perpendicular to the first direction D1. The second pixel rows R2 are disposed in the second display area A2 in the first direction D1, and the second pixel row R2 includes multiple second pixels PX2 disposed in the second direction D2.

The width W2 of the second pixel PX2 in the second direction D2 is substantially the same as the width W1 of the first pixel PX1 in the second direction D2, and the display medium of the second pixel PX2 is different from the display medium of the first pixel PX1. The display medium of the second pixel PX2 includes a first micro-LED E1, a second micro-LED E2 and a third micro-LED E3. In the second pixel PX2, two of the first micro-LED E1, the second micro-LED E2 and the third micro-LED E3 overlap in the first direction D1.

Since the display medium of the second pixel PX2 in the second display area A2 is micro-LEDs, and the display medium of the first pixel PX1 in the first display area A1 is different from the display medium of the second pixel PX2, an optical sensor can be superimposed in the second display area A2, which is a transparent display area. The display medium of the first pixel PX1 in the first display area A1, which is an opaque display area, may include liquid crystal units or OLEDs to perform general display functions, thereby avoiding excessively high production costs. Furthermore, because in the second pixel PX2, two of the first micro-LED E1, the second micro-LED E2 and the third micro-LED E3 overlap in the first direction D1, ensuring the width W2 of the second pixel PX2 in the second display area A2 matches the width W1 of the first pixel PX1 in the first display area A1. This prevents a noticeable screen tearing effect at the boundary between the first display area A1 and the second display area A2, thereby improving the display quality of the display device 10.

As shown in FIG. 2, in the second pixel PX2, the second micro-LED E2 and the third micro-LED E3 partially overlap in the first direction D1, but the present disclosure is not limited thereto. In other embodiments, in the second pixel PX2, the second micro-LED E2 and the third micro-LED E3 may completely overlap in the first direction D1, or the first micro-LED E1 and the second micro-LED E2 may partially or completely overlap in the first direction D1.

The second pixel PX2 is equally divided into a first horizontal region H1, a second horizontal region H2 and a third horizontal region H3 in sequence in the first direction D1, and one of the first micro-LED E1, the second micro-LED E2 and the third micro-LED E3 is disposed in the first horizontal region H1. For example, approximately more than half of the orthographic projection of one of the first micro-LED E1, the second micro-LED E2 and the third micro-LED E3 on the array substrate 100 is located in the first horizontal region H1. The aforementioned design avoids dark lines occurring at the position in the second display area A2 adjacent to the first display area A1, thereby improving the display quality of the display device 10.

In addition, the other two of the first micro-LED E1, the second micro-LED E2 and the third micro-LED E3 are disposed in the second horizontal region H2. For example, approximately more than half of the orthographic projection of each of the other two of the first micro-LED E1, the second micro-LED E2 and the third micro-LED E3 on the array substrate 100 is located in the second horizontal region H2. The aforementioned design avoids color shift in the second pixel PX2 in the second display area A2 due to uneven color mixing, thereby improving the display quality of the display device 10.

As shown in FIG. 2, approximately more than half of the orthographic projection of the third micro-LED E3 on the array substrate 100 is located in the first horizontal region H1, and approximately more than half of the orthographic projection of each of the first micro-LED E1 and the second micro-LED E2 on the array substrate 100 is located in the second horizontal region H2. In some embodiments, the first micro-LED E1, the second micro-LED E2 and the third micro-LED E3 may be a red micro-LED, a green micro-LED and a blue micro-LED, respectively.

That is, approximately more than half of the orthographic projection of the blue micro-LED E3 on the array substrate 100 is located in the first horizontal region H1, and approximately more than half of the orthographic projection of each of the red micro-LED E1 and the green micro-LED E2 on the array substrate 100 is located in the second horizontal region H2. The aforementioned design avoids dark lines occurring at the position in the second display area A2 adjacent to the first display area A1, and avoids color shift in the second pixel PX2 in the second display area A2 due to uneven color mixing, such as the occurring of obvious red, blue or yellow lines, thereby improving the display quality of the display device 10.

Referring to FIG. 2, the second pixel PX2 is equally divided into a first vertical region V1, a second vertical region V2 and a third vertical region V3 in sequence in the second direction D2. The first micro-LED E1, the second micro-LED E2 and the third micro-LED E3 are disposed in the vertical region V1, the second vertical region V2 and the third vertical region V3, respectively. For example, approximately more than half of the orthographic projection of the first micro micro-LED E1 on the array substrate 100 is located in the first vertical region V1, approximately more than half of the orthographic projection of the second micro-LED E2 on the array substrate 100 is located in the second vertical region V2, and approximately more than half of the orthographic projection of the third micro-LED E3 on the array substrate 100 is located in the third vertical region V3.

In addition, the first pixel PX1 includes a first sub-pixel P1, a second sub-pixel P2 and a third sub-pixel P3, and in the first pixel PX1, the first sub-pixel P1, the second sub-pixel P2 and the third sub-pixel P3 are arranged in sequence in the second direction D2. In some embodiments, the first sub-pixel P1, the second sub-pixel P2 and the third sub-pixel P3 may be a red sub-pixel, a green sub-pixel and a blue sub-pixel, respectively. In the first direction D1, approximately more than half of the red first micro-LED E1 overlaps the red first sub-pixel P1, approximately more than half of the green second micro-LED E2 overlaps the green second sub-pixel P2, and approximately more than half of the blue third micro-LED E3 overlaps the blue third sub-pixel P3. The aforementioned design enables the first display area A1 and the second display area A2 to have consistent color rendering of the displayed image, thereby improving the display quality of the display device 10.

FIG. 3 is an enlarged diagram of a region of an array substrate of a display device according to at least another embodiment of the present disclosure. Referring to FIG. 3, the structures and the relative positions of most elements in the embodiment of FIG. 3 and the embodiment of FIG. 2 are the same, and the schematic top view of the display device of FIG. 3 is substantially the same as the schematic top view of the display device 10 of FIG. 2, so the same features are not repeated here. The main difference between the two embodiments is that the first pixel PX1 in FIG. 3 includes a first sub-pixel P1, a second sub-pixel P2A and a third sub-pixel P3A, and in the first pixel PX1, two of the first sub-pixel P1, the second sub-pixel P2A and the third sub-pixel P3A overlap in the first direction D1.

As shown in FIG. 3, in the second pixel PX2, the second micro-LED E2 and the third micro-LED E3 partially overlap in the first direction D1, and in the first pixel PX1, the second sub-pixel P2A, which has the same color as the second micro-LED E2, and the third sub-pixel P3A, which has the same color as the third micro-LED E3, completely overlap in the first direction D1. For example, in the second pixel PX2, the green second micro-LED E2 and the blue third micro-LED E3 partially overlap in the first direction D1, and in the first pixel PX1, the green second sub-pixel P2A and the blue third sub-pixel P3A completely overlap in the first direction D1. The aforementioned design enables the first display area A1 and the second display area A2 to have consistent color rendering of the displayed image, thereby improving the display quality of the display device 10.

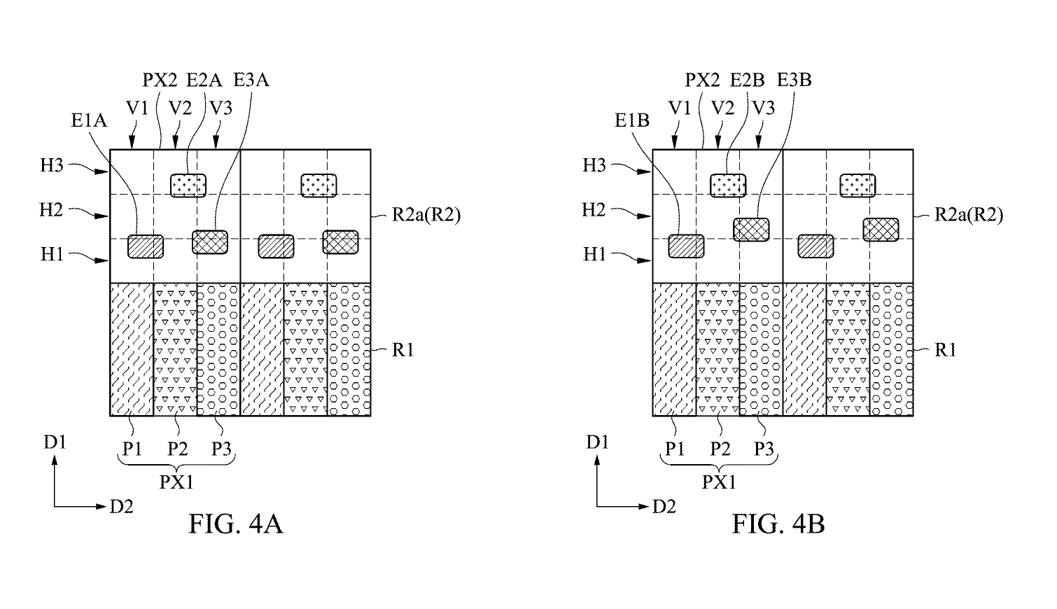

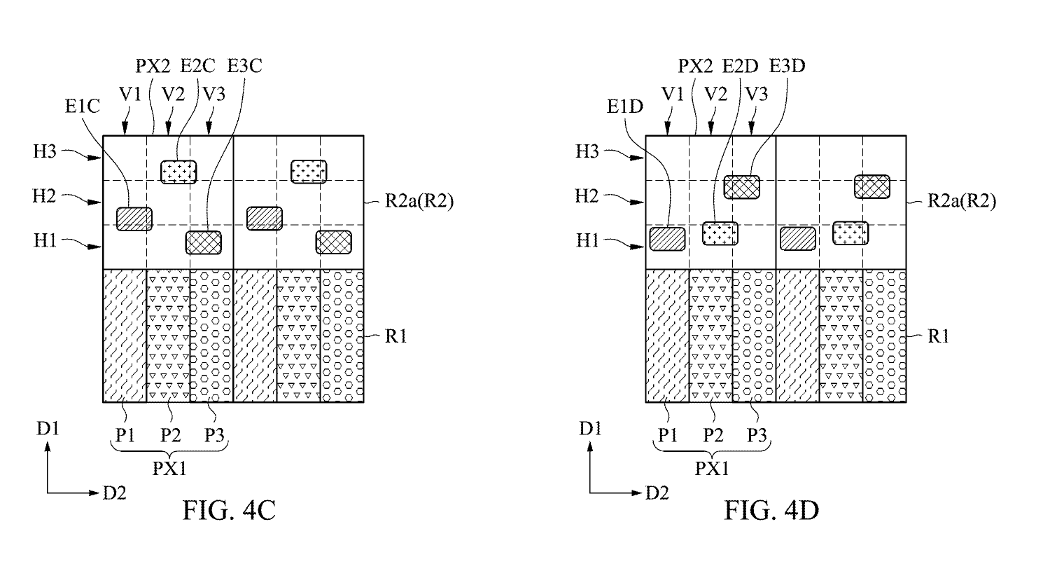

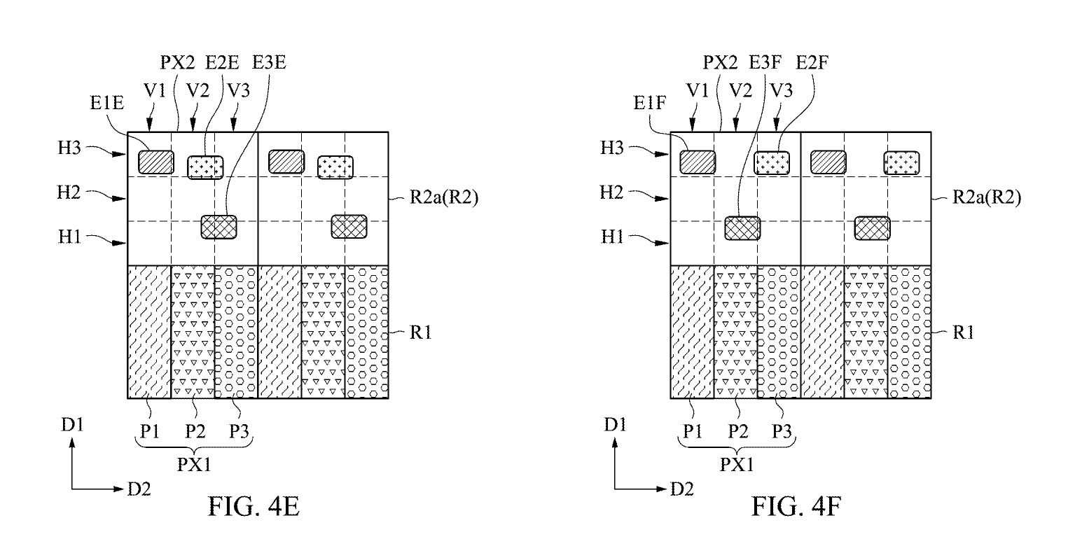

FIGS. 4A-4F are enlarged diagrams of regions of array substrates of display devices according to at least another embodiments of the present disclosure. The structures and the relative positions of most elements in the embodiments of FIGS. 4A-4F and the embodiment of FIG. 2 are the same, and the schematic top views of the display devices of FIGS. 4A-4F are substantially the same as the schematic top view of the display device 10 of FIG. 2, so the same features are not repeated here.

Referring to FIG. 4A, the difference between the embodiment of FIG. 4A and the embodiment of FIG. 2 is that approximately more than half of the orthographic projection of each of the red first micro-LED E1A and the blue third micro-LED E3A on the array substrate 100 is located in the first horizontal region H1, and approximately more than half of the orthographic projection of the green second micro-LED E2A on the array substrate 100 is located in the third horizontal region H3. That is, none of the red first micro-LED E1A, the green second micro-LED E2A and the blue third micro-LED E3A have more than half of their orthogonal projection on the array substrate 100 located in the second horizontal region H2. In this embodiment, obvious red and blue lines occurring at the position in the second display area A2 adjacent to the first display area A1 can be avoided by adjusting the grayscale brightness.

In detail, as shown in FIGS. 1 and 4A, the display device 10 further includes a driving circuit 200 electrically connected to the second pixel rows R2, which include a boundary pixel row R2a adjacent to the first display area A1. In the boundary pixel row R2a, the display brightness of one of the first micro-LED E1A, the second micro-LED E2A and the third micro-LED E3A disposed in the first horizontal area H1 is lower than the preset brightness set by the driving circuit 200.

In some embodiments, the display brightness is approximately 0.5 to 0.6 times the preset brightness. Furthermore, the preset brightness can be the grayscale brightness of one of the first micro-LED E1A, the second micro-LED E2A and the third micro-LED E3A disposed in the first horizontal region H1, which the driving circuit 200 originally predetermined to provide to the boundary pixel row R2a. Alternatively, the preset brightness can be the grayscale brightness of one of the first micro-LED E1A, the second micro-LED E2A and the third micro-LED E3A disposed in the first horizontal region H1, which the driving circuit 200 originally predetermined to provide to the second pixel row R2, which is adjacent to the boundary pixel row R2a.

For example, in the boundary pixel row R2a, the display brightness of the red first micro-LED E1A and the blue third micro-LED E3A disposed in the first horizontal region H1 are both lower than the preset brightness set by the driving circuit 200. By adjusting the grayscale brightness of the red first micro-LED E1A and the blue third micro-LED E3 disposed in the first horizontal region H1 of the boundary pixel row R2a, obvious red and blue lines occurring in the boundary pixel row R2a in the second display area A2 adjacent to the first display area A1 can be avoided.

Referring to FIG. 4B, the difference between the embodiment of FIG. 4B and the embodiment of FIG. 2 is that approximately more than half of the orthographic projection of the red first micro-LED E1B on the array substrate 100 is located in the first horizontal region H1, approximately more than half of the orthographic projection of the blue third micro-LED E3B on the array substrate 100 is located in the second horizontal region H2, and approximately more than half of the orthographic projection of the green second micro-LED E2B on the array substrate 100 is located in the third horizontal region H3. In this embodiment, obvious red lines occurring at the position in the second display area A2 adjacent to the first display area A1 can be avoided by adjusting the grayscale brightness.

For example, in the boundary pixel row R2a, the display brightness of the red first micro-LED E1B disposed in the first horizontal region H1 is lower than the preset brightness set by the driving circuit 200. By adjusting the grayscale brightness of the red first micro-LED E1B disposed in the first horizontal region H1 in the boundary pixel row R2a, obvious red lines occurring in the boundary pixel row R2a in the second display area A2 adjacent to the first display area A1 can be avoided.

Referring to FIG. 4C, the difference between the embodiment of FIG. 4C and the embodiment of FIG. 2 is that approximately more than half of the orthographic projection of the blue third micro-LED E3C on the array substrate 100 is located in the first horizontal region H1, approximately more than half of the orthographic projection of the red first micro-LED E1C on the array substrate 100 is located in the second horizontal region H2, and approximately more than half of the orthographic projection of the green second micro-LED E2C on the array substrate 100 is located in the third horizontal region H3. In this embodiment, obvious red and blue lines occurring at the position in the second display area A2 adjacent to the first display area A1 can be avoided by adjusting the grayscale brightness.

For example, in the boundary pixel row R2a, the display brightness of the blue third micro-LED E3C disposed in the first horizontal region H1 and the display brightness of the red first micro-LED E1C disposed in the second horizontal region H2 are both lower than the preset brightness set by the driving circuit 200. By adjusting the grayscale brightness of the blue third micro-LED E3C disposed in the first horizontal region H1 and the grayscale brightness of the red first micro-LED E1C disposed in the second horizontal region H2, obvious red and blue lines occurring in the boundary pixel row R2a in the second display area A2 adjacent to the first display area A1 can be avoided.

Referring to FIG. 4D, the difference between the embodiment of FIG. 4D and the embodiment of FIG. 2 is that approximately more than half of the orthographic projection of each of the red first micro-LED E1D and the green second micro-LED E2D on the array substrate 100 is located in the first horizontal region H1, and approximately more than half of the orthographic projection of the blue third second micro-LED E3D on the array substrate 100 is located in the second horizontal region H2. In this embodiment, obvious yellow lines occurring at the position in the second display area A2 adjacent to the first display area A1 can be avoided by adjusting the grayscale brightness.

For example, in the boundary pixel row R2a, the display brightness of the red first micro-LED E1D and the display brightness of the green second micro-LED E2D disposed in the first horizontal region H1 are both lower than the preset brightness set by the driving circuit 200. By adjusting the grayscale brightness of the red first micro-LED E1D and the green second micro-LED E2D disposed in the first horizontal region H1 in the boundary pixel row R2a, obvious yellow lines occurring in the boundary pixel row R2a in the second display area A2 adjacent to the first display area A1 can be avoided.

Referring to FIG. 4E, the difference between the embodiment of FIG. 4E and the embodiment of FIG. 2 is that approximately more than half of the orthographic projection of the blue third micro-LED E3E on the array substrate 100 is located in the first horizontal region H1, and approximately more than half of the orthographic projection of each of the red first micro-LED E1E and the green second micro-LED E2E on the array substrate 100 is located in the third horizontal region H3. That is, none of the red first micro-LED E1E, the green second micro-LED E2E and the blue third micro-LED E3E have more than half of their orthogonal projection on the array substrate 100 located in the second horizontal region H2. In this embodiment, obvious blue lines occurring at the position in the second display area A2 adjacent to the first display area A1 can be avoided by adjusting the grayscale brightness.

For example, in the boundary pixel row R2a, the display brightness of the blue third micro-LED E3E disposed in the first horizontal region H1 is lower than the preset brightness set by the driving circuit 200. By adjusting the grayscale brightness of the blue third micro-LED E3E disposed in the first horizontal region H1 in the boundary pixel row R2a, obvious blue lines occurring in the boundary pixel row R2a in the second display area A2 adjacent to the first display area A1 can be avoided.

Referring to FIG. 4F, the difference between the embodiment of FIG. 4F and the embodiment of FIG. 2 is that approximately more than half of the orthographic projection of the blue third micro-LED E3F on the array substrate 100 is located in the first horizontal region H1, and approximately more than half of the orthographic projection of each of the red first micro-LED E1F and the green second micro-LED E2F on the array substrate 100 is located in the third horizontal region H3. That is, none of the red first micro-LED E1F, the green second micro-LED E2F and the blue third micro-LED E3F have more than half of their orthogonal projection on the array substrate 100 located in the second horizontal region H2, approximately more than half of the orthographic projection of the red first micro-LED E1F on the array substrate 100 is located in the first vertical region V1, approximately more than half of the orthographic projection of the blue third micro-LED E3F on the array substrate 100 is located in the second vertical region V2, and approximately more than half of the orthographic projection of the green second micro-LED E2F on the array substrate 100 is located in the third vertical region V3. In this embodiment, obvious blue lines occurring at the position in the second display area A2 adjacent to the first display area A1 can be avoided by adjusting the grayscale brightness.

For example, in the boundary pixel row R2a, the display brightness of the blue third micro-LED E3F disposed in the first horizontal area H1 is lower than the preset brightness set by the driving circuit 200. By adjusting the grayscale brightness of the blue third micro-LED E3F disposed in the first horizontal area H1 in the boundary pixel row R2a, obvious blue lines occurring in the boundary pixel row R2a in the second display area A2 adjacent to the first display area A1 can be avoided.

In summary, in at least one embodiment of the display device of the present disclosure, since the display medium of the second pixel disposed in the second display area is micro-LEDs, and the display medium of the first pixel disposed in the first display area is different from the display medium of the second pixel, an optical sensor can be superimposed on the second display area which is a transparent display area, and the display medium of the first pixel of the first display area which is an opaque display area may include liquid crystal units or OLEDs to perform general display functions, thereby avoiding excessively high production costs. Furthermore, since two of the first micro-LED, the second micro-LED and third micro-LED in the second pixel overlap each other, the width of the second pixel in the second display area matches the width of the first pixel in the first display area. This prevents a noticeable screen tearing effect at the boundary between the first display area and the second display area, thereby improving the display quality of the display device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display device, comprising:
an array substrate, having a first display area and a second display area adjacent to the first display area, and comprising:
a plurality of first pixel rows, disposed in the first display area in a first direction, wherein each of the first pixel rows comprises a plurality of first pixels disposed in a second direction perpendicular to the first direction; and
a plurality of second pixel rows, disposed in the second display area in the first direction, wherein each of the second pixel rows comprises a plurality of second pixels disposed in the second direction, wherein a width of each of the second pixels in the second direction is the same as a width of each of the first pixels in the second direction, and a display medium of each of the second pixels is different from a display medium of each of the first pixels, wherein the display medium of each of the second pixels comprises a first micro-LED, a second micro-LED and a third micro-LED, and in each of the second pixels, two of the first micro-LED, the second micro-LED and the third micro-LED overlap in the first direction.

2. The display device of claim 1, wherein the display medium of each of the first pixels comprises a liquid crystal unit or an OLED.

3. The display device of claim 1, wherein each of the second pixels is equally divided into a first horizontal region, a second horizontal region, and a third horizontal region in sequence in the first direction, and one of the first micro-LED, the second micro-LED and the third micro-LED is disposed in the first horizontal region.

4. The display device of claim 3, wherein the one of the first micro-LED, the second micro-LED and the third micro-LED disposed in the first horizontal region is a blue micro-LED.

5. The display device of claim 3, wherein more than half of a orthographic projection of the one of the first micro-LED, the second micro-LED and the third micro-LED on the array substrate is located in the first horizontal region.

6. The display device of claim 3, wherein the other two of the first micro-LED, the second micro-LED and the third micro-LED are disposed in the second horizontal region.

7. The display device of claim 6, wherein more than half of a orthographic projection of each of the other two of the first micro-LED, the second micro-LED and the third micro-LED is located in the second horizontal region.

8. The display device of claim 3, further comprising a driving circuit electrically connected to the second pixel rows, wherein the second pixel rows comprise a boundary pixel row adjacent to the first display area, and in the boundary pixel row, a display brightness of the one of the first micro-LED, the second micro-LED and the third micro-LED disposed in the first horizontal region is lower than a preset brightness set by the driving circuit.

9. The display device of claim 8, wherein the display brightness is 0.5 to 0.6 times the preset brightness.

10. The display device of claim 1, wherein each of the first pixels includes a first sub-pixel, a second sub-pixel and a third sub-pixel, and in each of the first pixels, the first sub-pixel, the second sub-pixel and the third sub-pixel are arranged in sequence in the second direction.

11. The display device of claim 1, wherein each of the first pixels includes a first sub-pixel, a second sub-pixel and a third sub-pixel, and in each of the first pixels, two of the first sub-pixel, the second sub-pixel and the third sub-pixel overlap in the first direction.

12. The display device of claim 11, wherein colors of the two of the first sub-pixel, the second sub-pixel and the third sub-pixel overlap in the first direction are as the same as colors of the two of the first micro-LED, the second micro-LED and the third micro-LED overlap in the first direction, respectively.

13. The display device of claim 1, wherein the first display area is an opaque display area, and the second display area is a transparent display area.

14. A display device, comprising:
an array substrate, having a first display area and a second display area adjacent to the first display area, and comprising:
a plurality of first pixel rows, disposed in the first display area in a first direction, wherein each of the first pixel rows comprises a plurality of first pixels disposed in a second direction perpendicular to the first direction; and
a plurality of second pixel rows, disposed in the second display area in the first direction, wherein each of the second pixel rows comprises a plurality of second pixels disposed in the second direction, wherein a width of each of the second pixels in the second direction is the same as a width of each of the first pixels in the second direction, and a display medium of each of the second pixels is different from a display medium of each of the first pixels, wherein the display medium of each of the second pixels comprises a first micro-LED, a second micro-LED and a third micro-LED, and each of the second pixels is equally divided into a first horizontal region, a second horizontal region, and a third horizontal region in sequence in the first direction, wherein one of the first micro-LED, the second micro-LED and the third micro-LED is disposed in the first horizontal region, and more than half of a orthographic projection of the one of the first micro-LED, the second micro-LED and the third micro-LED on the array substrate is located in the first horizontal region.

15. The display device of claim 14, wherein the other two of the first micro-LED, the second micro-LED and the third micro-LED are disposed in the second horizontal region, and more than half of a orthographic projection of each of the other two of the first micro-LED, the second micro-LED and the third micro-LED is located in the second horizontal region.
